(19) United States
(12) Patent Application Publication
(10) Pub. No.: US 2008/0265926 A1
(43) Pub. Date: Oct. 30, 2008

(54) TEST HEAD

(75) Inventor: Yasuyuki Kawasumi, Musashino-shi (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION, Tokyo (JP)

(21) Appl. No.: 12/107,482

(22) Filed: Apr. 22, 2008

(30) Foreign Application Priority Data
Apr. 24, 2007 (JP) 2007-114529

(51) Int. Cl. G01R 31/02

(52) U.S. Cl. 324/761

(57) ABSTRACT

Disclosed is a test head comprising: a supporting member configured on an end face of a test head housing on a side of connection with a device under test; a pin electronics circuit disposed in the test head housing, the pin electronics circuit outputting a test signal; flexible wiring including one end connected to the pin electronics circuit and another end provided to elongate onto the supporting member on an outside of the test head housing; and a connection section with a side of the device under test, the connection section annexed on the other end of the flexible wiring, wherein a load loaded at a time of connection of the device under test to the connection section is supported by the supporting member.

### BACKGROUND OF THE INVENTION

1. Field of the Invention

The present invention relates to a test head of an IC tester for testing an integrated circuit (IC), a large scale integrated circuit (LSI), and the like, and more particularly to a connection structure between a device under test and pin electronics.

2. Related Art

The IC tester gives a test signal to a device under test (hereinafter referred to as “DUT”), such as an IC and an LSI, to judge the quality of the DUT on the basis of a response from the DUT.

FIGS. 3A-5 show an example of the test head of a conventional IC tester. FIG. 3A is a plan view of the test head, and FIG. 3B is a longitudinal section of the test head. FIG. 4A is a plan view of the part of one DUT board, and FIG. 4B is a longitudinal section of the part of the DUT board. FIG. 5 is a bottom view of the part of the DUT board.

The related art test head is a test head of the system in which a plurality of sockets 12 for the connection with DUTs 11 is arranged on one end face to connect each of the DUTs 11 with each of the sockets 12 by handling the DUT 11.

As shown in FIGS. 3A-5, a plurality of pin electronics circuits 19 housed in a test head housing 301 is electrically connected to the plurality of sockets 12 mounted on DUT boards 13 through respective coaxial cables 17 and the respective DUT boards 13.

Each of the DUT boards 13 is a wiring board in which wiring, such as vias 101 and board wiring 102, are formed. Connectors 16 are annexed on the back surface of the DUT board 13, which faces the inside of the test head housing 301. A socket 12 is annexed on the front surface of the DUT board 13, which faces the outside of the test head housing 301. Coaxial cables 17 provided to elongate from the pin electronics circuits 19 are connected to the connectors 16. Each of the DUTs 11 connected to the socket 12 is electrically connected to each of the pin electronics circuits 19 through the coaxial cables 17, the connectors 16, each of the DUT boards 13, and the socket 12, and the transfers of signals between them and the supply of electric power to the DUT 11 are performed.

A DUT board supporting rigid body 18 is integrally fixed on the end face of the test head housing 301 on the DUT connecting side. Openings 18a are formed in the DUT board supporting rigid body 18 in correspondence with the DUT boards 13. The DUT boards 13 are disposed on the outside of the DUT board supporting rigid body 18 so as to cover the openings 18a, respectively. The DUT boards 13 are fixed to the DUT board supporting rigid body 18 with DUT board fixing screws 15 or the like. The sockets 12 are fixed on the DUT boards 13 with socket fixing screws 14 or the like.

The DUT boards 13 and the DUT board supporting rigid body 18 support the load loaded at the time when the DUTs 11 are inserted into the sockets 12, respectively, with a handler apparatus or the like.

On the other hand, the test head described in Japanese Utility Model Application Laid-Open No. Hei 5-11075 adopts a flexible printed circuit board in place of the coaxial cables.

However, as described above, the DUT boards 13 are equipped with both of a signal transmitting function between the pin electronics circuits 19 and the DUTs 11, and the function of supporting the load loaded at the time when the DUTs 11 are connected. That is, the DUT boards 13 are required to have sufficient mechanical strength besides good signal transmission characteristics.

Thick printed wiring boards having sufficient mechanical strength to bear the load loaded at the time of DUT connection consequently becomes necessary as the DUT boards 13, and the thick printed wiring boards cause the problem of the deterioration of high frequency signal transmission characteristics at the vias 101 and the board wiring 102 of the DUT boards 13.

Incidentally, in case of a test head to be connected with a prober, the situation is the same because the load loaded at the time of the connection with the prober is borne also by a probe card.

Moreover, because the DUT boards 13 need mounting areas of the connectors 16, it has been difficult to realize the miniaturization and the densification of the DUT boards 13 and therefore the test head.

### SUMMARY

The present invention was made in view of the problems of the related art mentioned above, and aims to provide a test head having the structure capable of improving the high frequency signal transmission characteristics from the pin electronics circuits to the devices under test, the structure advantageous for the miniaturization and the densification thereof.

According to an aspect of the present invention, there is provided a test head comprising: a supporting member configured on an end face of a test head housing on a side of connection with a device under test; a pin electronics circuit disposed in the test head housing, the pin electronics circuit outputting a test signal; flexible wiring including one end connected to the pin electronics circuit and another end provided to elongate onto the supporting member on an outside of the test head housing; and a connection section with a side of the device under test, the connection section annexed on the other end of the flexible wiring, wherein a load loaded at a time of connection of the device under test to the connection section is supported by the supporting member.

Hereupon, the flexible wiring indicates wiring deforming in such a way that an arrangement can be changed. The flexible wiring includes various cables such as a coaxial cable or the like besides a flexible print wiring board.

Preferably, the flexible wiring passed through a hole formed in the supporting member to be drawn around from an inside of the test head housing to the outside thereof.

### BRIEF DESCRIPTION OF THE DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1A is a plan view of a part of one DUT board of a test head according to an embodiment of the present invention;

FIG. 1B is a longitudinal section of the part of the DUT board of the test head according to the embodiment of the present invention;

FIG. 2 is a bottom view of the part of the DUT board according to the embodiment of the present invention;

FIG. 3A is a plan view of a conventional test head;

FIG. 3B is a longitudinal section of the conventional test head;

FIG. 4A is a plan view of the part of one DUT board of the conventional test head;

FIG. 4B is a longitudinal section of the part of the DUT board of the conventional test head; and

FIG. 5 is a bottom view of the part of the DUT board of the conventional test head.

### DETAILED DESCRIPTION OF THE PREFERRED EMBODIMENTS

In the following, an embodiment of the present invention will be described with reference to the attached drawings. The following descriptions concern one embodiment of the present invention, and do not intend to limit the scope of the present invention.

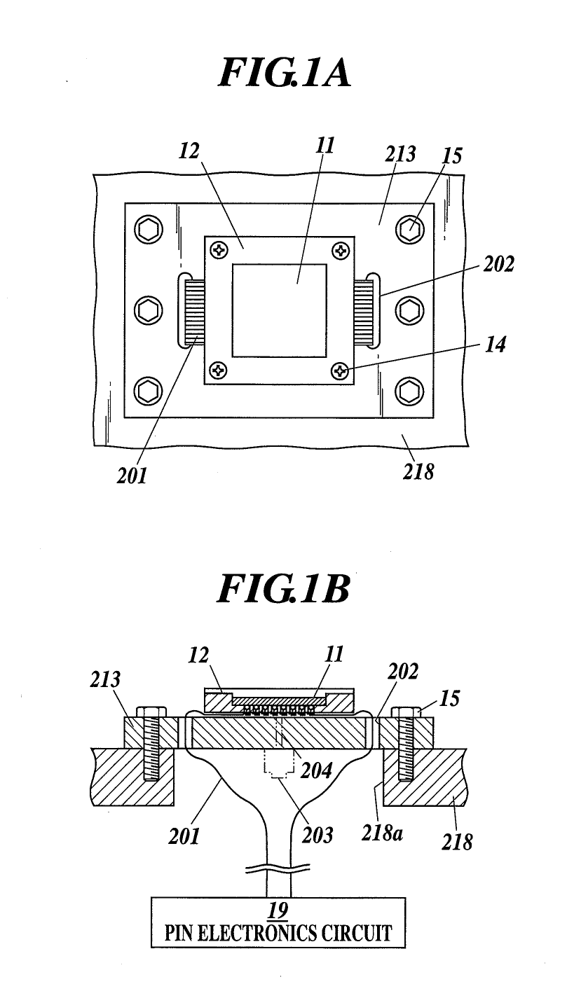

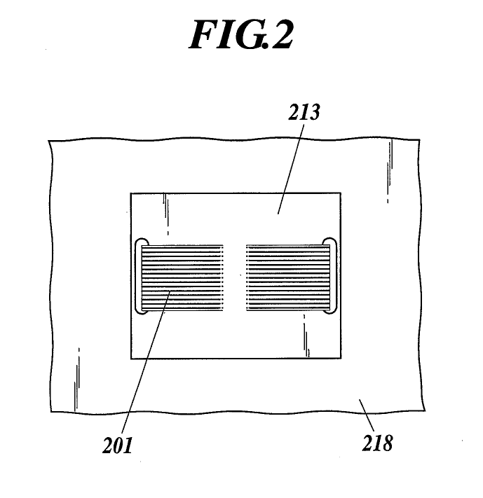

FIG. 1A is a plan view of the part of a DUT board of a test head according to an embodiment of the present invention, and FIG. 1B is a longitudinal section of the part of the DUT board according to the embodiment of the present invention. FIG. 2 is a bottom view of the part of the DUT board according to the embodiment of the present invention.

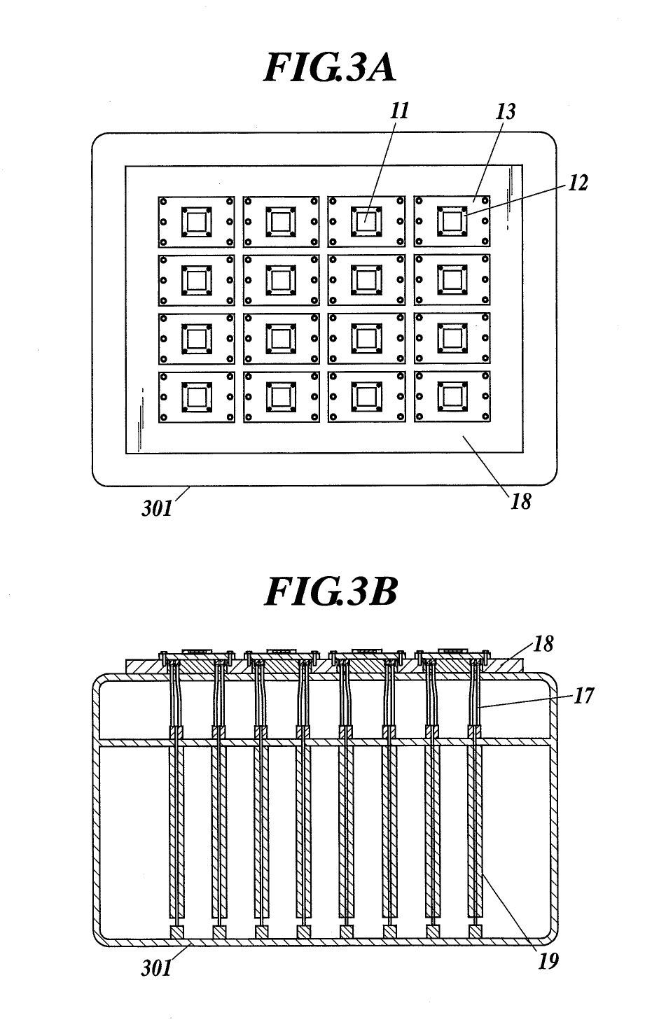

Similarly to the related art test head shown in FIGS. 3A and 3B, the test head of the present embodiment is a test head of the system in which a plurality of sockets 12 for the connection with DUTs 11 is arranged on one end face to connect each of the DUTs 11 with each of the sockets 12 by handling the DUT 11. The DUTs 11 are IC packages.

Similarly to the related art test head shown in FIGS. 3A and 3B, the test head of the present embodiment is provided with a plurality of pin electronics circuits 19 housed in a test head housing.

A DUT board supporting rigid body 218 as a supporting member and DUT boards 213 fixed to the DUT board supporting rigid body 218 are configured on the end face of a test head housing on the side of the connection with the DUTs 11.

The DUT board supporting rigid body 218 is integrally fixed on the end face of the test head housing on the DUT connecting side. Openings 218a are formed in the DUT board supporting rigid body 218 in correspondence with the DUT boards 213. The DUT boards 213 are disposed on the outside of the DUT board supporting rigid body 218 so as to cover the openings 218a, respectively. The DUT boards 213 are fixed to the DUT board supporting rigid body 218 with DUT board fixing screws 15 or the like. The sockets 12 are fixed on the DUT boards 213 with socket fixing screws 14 or the like.

Wiring holes 202 are formed in each of the DUT boards 213. One end of a flexible print wiring board 201 is connected to one of the pin electronics circuits 19. The other end of the flexible print wiring board 201 is provided to elongate on the DUT board 213 on the outside of the test head housing. In this case, the flexible print wiring board 201 is passed through one of the wiring holes 202 to be drawn around from the inside of the test head housing to the outside thereof.

An electrode terminal formed on the top surface of the other end of the flexible print wiring board 201, which the other end extends on the DUT board 213, and an electrode terminal formed on the bottom face of each of the sockets 12 are connected to each other, and consequently the flexible print wiring board 201 and the socket 12 are connected to each other.

The DUT 11 connected to the socket 12 and the pin electronics circuit 19 are electrically connected to each other through the flexible print wiring board 201 and the socket 12, and the transfers of signals between both of them and the supply of electric power to the DUT 11 are performed. The DUT board 213 and the DUT board supporting rigid body 218 support the load loaded at the time when the DUT 11 is inserted into the socket 12 with a handler apparatus or the like.

That is, the sockets 12 of the present embodiment are the connection sections with the side of the DUTs 11, and the loads loaded on the connection sections at the time of connection are supported by the DUT boards 213 and the DUT board supporting rigid body 218, which are supporting members.

As described above, because the pin electronics circuits 19 and the sockets 12 are mutually connected only by the flexible print wiring boards 201, the elements, such as the vias 101 and the connectors 16, which are configured on the conventional DUT boards 13 and deteriorate signal waveforms, are excluded, and the high frequency signal transmission characteristics from the pin electronics circuits 19 to the DUTs 11 are improved.

It is enough for the improvement of the high frequency signal transmission characteristics to configure only high frequency signal lines as the flexible print wiring board 201. Power wires and direct current signal wires may be configured as the flexible print wiring boards 201.

Alternatively, as shown by a broken line in FIG. 1B, connectors 203 and wiring 204 on the DUT boards 213 (vias and wiring drawn around on the DUT boards 213 as the need arises), which are similar to those of the related art mentioned above, are provided, and cables (not shown) provided to elongate from the pin electronics circuits 19 are connected to the connectors 203. The power wires and the direct current signal wires may be thus arranged. In this case, the wiring 204 may be connected to the sockets 12 with or without electroconductive members provided on the flexible print wiring boards 201. It is possible to directly connect the wiring 204 with the sockets 12 in a region except for those where the flexible print wiring boards 201 are provided on the DUT boards 213. Alternatively, holes may be formed in the flexible print wiring board 201, and the wiring 204 and the sockets 12 may be directly connected to each other through the holes. The high frequency signal lines on the flexible print wiring boards 201 can be increased by providing the power wires and the direct current signal wires by using cables other than the flexible print wiring boards 201.

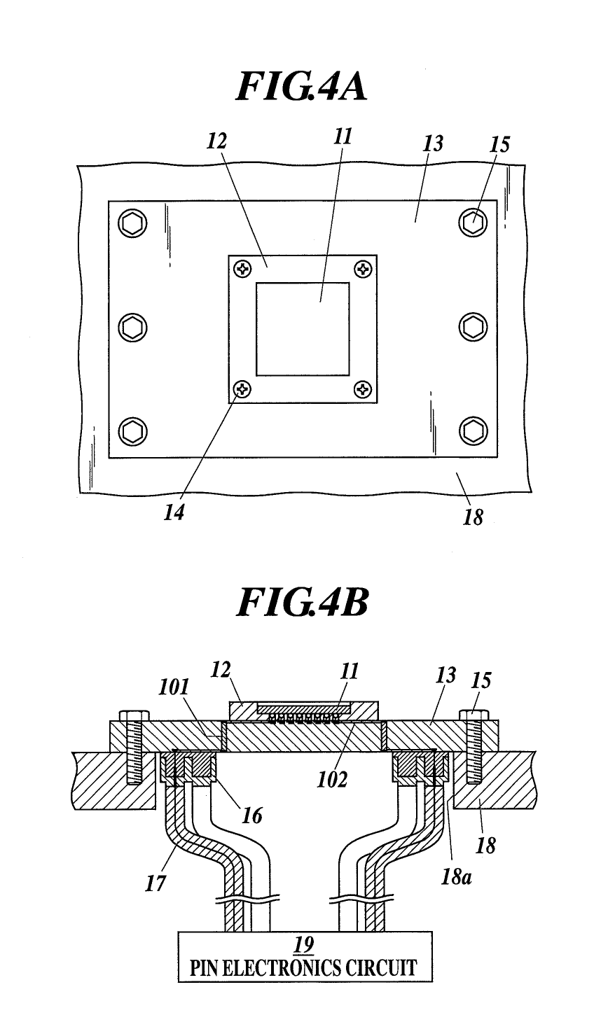

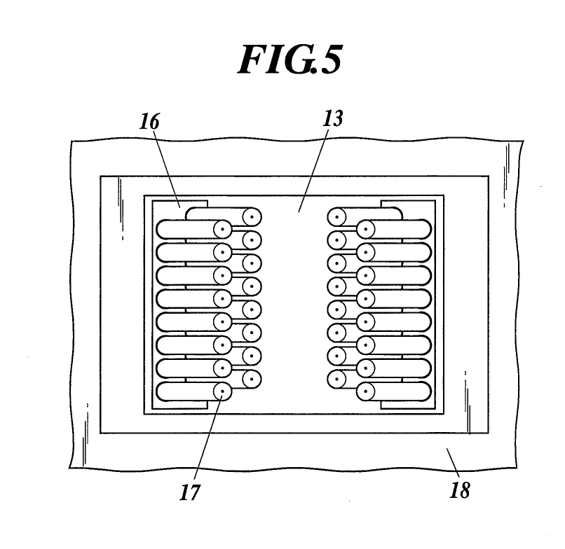

Moreover, by the configuration described above, the DUT boards 213 and openings 218a can be formed to be smaller than the corresponding ones of the related art shown in FIGS. 4A and 4B. The DUT boards 213, and therefore, the test head can be miniaturized and densified. That is, the number of the DUTs that can be mounted can be made to be larger if the size of the test head is same. Moreover, the miniaturization of the test head itself can be performed if the number of the DUTs is same.

Although IC packages are supposed as the DUTs 11 in the embodiment described above, the present invention can be also applied to DUTs formed as wafers. In the case of the DUTs formed as wafers, probe cards are applied in place of the DUT boards 213, and the test head is led to be equipped with the probe cards supporting the loads at the time of the connection of DUTs, and the flexible wiring constituting high frequency signal wiring.

Moreover, the wiring is not limited to the flexible print wiring board. Wiring having high wiring density enabling a small occupation space is preferable. Wiring in which at least the part disposed on a DUT boards is flat is preferable for annexing the connection sections such as a socket 12.

Moreover, although the electrodes touching the DUTs 11 are configured in the sockets 12 in the embodiment described above, the connection sections with the DUT sides may be annexed by forming electrodes touching the DUTs 11 on the flexible print wiring boards without using the parts such as the sockets 12.

Although the DUT boards 213 and the DUT board supporting rigid body 218 constitute the supporting members supporting the loads loaded at the time of the connection to the connection sections on the DUT sides in the embodiment described above, elemental substances in which the DUT boards 213 and the DUT board supporting rigid body 218 are integrated may be adopted, or further they may constitute a part of the test head housing.

Moreover, although the wiring holes 202 are formed in the DUT boards 213 in the embodiment described above, the wiring holes 202 may be formed, for example, in the DUT board supporting rigid body 218. That is, the provision places, the forms, the number, and the like, of the wiring holes are arbitrary.

According to the present invention, the loads loaded at the time of the connection with the sides of the devices under test are supported by the supporting members (e.g. the DUT boards 213 and the DUT board supporting rigid body 218) configured on the end face of the test head housing 301 on the connection sides with the devices under test, and the wiring from the pin electronics circuits 19 to the connection sections with the sides of the devices under test is performed by the flexible wiring separated from the supporting members. Consequently, according to the present invention, the signal transmission characteristics are determined by the flexible wiring, and the mechanical strength bearing the loads at the time of connection is determined by the supporting members. Therefore the parts assuming both the functions are separated from each other.

Consequently, according to the present invention, the advantage of enabling the improvement of the high frequency signal transmission characteristics from the pin electronics circuits 19 to the devices under test of a test head is provided.

Moreover, according to the present invention, flexible wiring is provided to elongate onto the supporting members, and the wiring from the pin electronics circuits 19 to the connection sections with the sides of the devices under test is performed by the flexible wiring.

Consequently, according to the present invention, the advantage of enabling the exclusion of the connectors 16 in the wiring from the pin electronics circuits 19 to the connection sections with the sides of the devices under test to achieve the miniaturization and the densification of a test head is provided.

The entire disclosure of Japanese Patent Application No. 2007-114529 filed on Apr. 24, 2007 including description, claims, drawings, and abstract are incorporated herein by reference in its entirety.

What is claimed is:

1. A test head comprising:
a supporting member configured on an end face of a test head housing on a side of connection with a device under test;
a pin electronics circuit disposed in the test head housing, the pin electronics circuit outputting a test signal;
flexible wiring including one end connected to the pin electronics circuit and another end provided to elongate onto the supporting member on an outside of the test head housing; and
a connection section with a side of the device under test, the connection section annexed on the other end of the flexible wiring, wherein
a load loaded at a time of connection of the device under test to the connection section is supported by the supporting member.

2. The test head according to claim 1, wherein the flexible wiring passed through a hole formed in the supporting member to be drawn around from an inside of the test head housing to the outside thereof.
